(19) United States
(12) Patent Application Publication
(10) Pub. No.: US 2024/0194847 A1
(43) Pub. Date: Jun. 13, 2024

(54) DISPLAY DEVICE AND METHOD OF MANUFACTURING THE SAME

(71) Applicant: Samsung Display Co., LTD., Yongin-si (KR)

(72) Inventors: SI JOON SONG, Yongin-si (KR); DONGHYUN LEE, Yongin-si (KR); YOUN-WOONG KANG, Yongin-si (KR); MINSANG KOO, Yongin-si (KR); MISUN KIM, Yongin-si (KR); SEOKHYUN NAM, Yongin-si (KR); JAEHAK LEE, Yongin-si (KR)

(73) Assignee: Samsung Display Co., LTD., Yongin-si (KR)

(21) Appl. No.: 18/487,985

(22) Filed: Oct. 16, 2023

(30) Foreign Application Priority Data
Dec. 13, 2022 (KR) 10-2022-0174102

(51) Int. Cl. H01L 33/62; H01L 25/075; H01L 25/16; H01L 27/12

(52) U.S. Cl. CPC H01L 33/62; H01L 25/0753; H01L 25/167; H01L 27/1244; H01L 2933/0066

(57) ABSTRACT

A display device includes a first substrate having a flexibility, a pad electrode disposed on the first substrate, a driving member including connection wires extending in a first direction and electrically connected to the pad electrode and a flexible film connected to the connection wires, and connection electrodes disposed between the pad electrode and the connection wires and arranged to define a plurality of rows extending in a second direction intersecting the first direction in a plan view.

### CROSS REFERENCE TO RELATED APPLICATION(S)

This application claims priority to and benefits of Korean Patent Application No. 10-2022-0174102 under 35 U.S.C. § 119, filed in the Korean Intellectual Property Office (KIPO) on Dec. 13, 2022, the entire contents of which are incorporated herein by reference.

### BACKGROUND

### 1. Technical Field

The disclosure relates to a display device and a method of manufacturing the display device. More specifically, the disclosure relates to a display device having a back bonding structure and a method of manufacturing the display device.

### 2. Description of the Related Art

As information technology develops, importance of a display device as a connection medium between a user and information is being highlighted. For example, a use of display devices such as a liquid crystal display device (LCD), an organic light emitting display device (OLED), a plasma display device (PDP), a quantum dot display device, or the like is increasing.

In general, the display device has a display area where pixels are arranged and a non-display area surrounding the display area. As a method for reducing the non-display area, a back bonding structure is being studied.

### SUMMARY

Embodiments provide a display device with improved reliability and improved display quality.

The technical objectives to be achieved by the disclosure are not limited to those described herein, and other technical objectives that are not mentioned herein would be clearly understood by a person skilled in the art from the description of the disclosure.

Embodiments provide a method for manufacturing the display device.

A display device according to an embodiment includes a first substrate having a flexibility, a pad electrode disposed on the first substrate, a driving member including connection wires extending in a first direction and electrically connected to the pad electrode and a flexible film connected to the connection wires, and connection electrodes disposed between the pad electrode and the connection wires and arranged to define a plurality of rows extending in a second direction intersecting the first direction in a plan view.

In an embodiment, the connection wires and the pad electrode may be electrically connected through the connection electrodes.

In an embodiment, the connection electrodes of a first row among the plurality of rows may be disposed between the connection electrodes of a second row most adjacent to the first row among the plurality of rows in a plan view.

In an embodiment, the display device may further include bonding patterns overlapping the connection wires and the connection electrodes in a plan view and arranged to define a plurality of rows extending in the second direction in a plan view.

In an embodiment, the connection wires and the connection electrodes may be bonded by the bonding patterns.

In an embodiment, the first substrate may have an opening exposing portions of each of the connection electrodes, and the connection wires and the connection electrodes may be bonded by the bonding patterns in the opening.

In an embodiment, the bonding patterns of a first row among the plurality of rows may be disposed between the bonding patterns of a second row most adjacent to the first row among the plurality of rows in a plan view.

In an embodiment, the bonding patterns may include a conductive material.

In an embodiment, the conductive material included in each of the bonding patterns may include at least one selected from silver, copper, chromium, and aluminum.

In an embodiment, the display device may further include a second substrate disposed on the first substrate, and the connection electrodes may be disposed between the first substrate and the second substrate.

In an embodiment, the second substrate may have a through hole exposing portions of each of the connection electrodes, and the pad electrode may be electrically connected to the connection electrodes through the through hole.

In an embodiment, the display device may further include a barrier layer including a first barrier layer disposed on the first substrate and a second barrier layer disposed between the first barrier layer and the second substrate, and the connection electrodes and the barrier layer may be disposed on a same layer.

In an embodiment, end portions of the connection wires may protrude further in the first direction than an end portion of the flexible film.

In an embodiment, the flexible film may have film openings exposing portions of each of the connection wires and arranged to define a plurality of rows extending in the second direction in a plan view, and the connection electrodes may overlap the film openings in a plan view, respectively.

A method of manufacturing a display device according to an embodiment includes forming a display panel including a first substrate having a flexibility, a pad electrode disposed on the first substrate, and connection electrodes electrically connected to the pad electrode, attaching a driving member including connection wires extending in a first direction and a flexible film connected to the connection wires to the display panel such that portions of each of the connection wires overlaps the connection electrodes in a plan view, respectively, and bonding the driving member and the display panel by providing a conductive bonding material on the connection wires overlapping the connection electrodes in a plan view, and the connection electrodes may be arranged to define a plurality of rows extending in a second direction intersecting the first direction.

In an embodiment, the method further include removing a portion of the flexible film so that end portions of the connection wires protrude further in the first direction than an end portion of the flexible film before the attaching of the driving member to the display panel, and after the attaching of the driving member to the display panel, the connection electrodes may overlap portions of the connection wires exposed from the flexible film in a plan view, respectively.

In an embodiment, in the bonding of the driving member and the display panel, the conductive bonding material may be ejected onto the connection wires overlapping the connection electrodes in a plan view by an inkjet printing process.

In an embodiment, the bonding of the driving member and the display panel may include disposing a mask having mask openings arranged to define a plurality of rows extending in the second direction on the connection wires exposed from the flexible film and providing the conductive bonding material on the connection wires through the mask openings, and after the disposing of the mask, the mask openings may overlap the connection electrodes in a plan view, respectively.

In an embodiment, the method may further include forming film openings exposing portions of each of the connection wires in the flexible film before attaching the driving member to the display panel, and after attaching the driving member to the display panel, the connection electrodes may overlap the film openings in a plan view, respectively.

In an embodiment, in the bonding of the driving member and the display panel, the conductive bonding material may be provided on the connection wires through the film openings to bond the connection wires and the connection electrode.

The display device according to embodiments may include the display panel and the driving member. The substrate layer included in the display panel may include the first substrate, the second substrate, and the connection electrodes disposed between the first substrate and the second substrate. The pad electrode disposed on the substrate layer may be electrically connected to the connection electrodes through the through holes penetrating the second substrate. Also, the connection wires of the driving member may be electrically connected to the connection electrodes. Accordingly, the pad electrode and the connection wires may be electrically connected through the connection electrodes. Accordingly, the driving member may be bonded to the rear surface of the display panel. Thus, a dead space of the display device may be reduced.

In addition, the connection electrodes may be arranged in a zigzag pattern in a plan view. For example, the connection electrodes may be arranged to define a plurality of rows extending in one direction, and the connection electrodes of the first row among the plurality of rows may be disposed between the connection electrodes of the second row most adjacent to the first row among the plurality of rows. Accordingly, the connection electrodes may be arranged at a minute interval from each other, but bonding defects between the connection electrodes and the connection wires may be prevented or reduced. Accordingly, reliability of the display device may be improved and display quality may be improved.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a schematic plan view illustrating a display device according to an embodiment.

FIG. 2 is a schematic cross-sectional view taken along line I-I′ in FIG. 1.

FIG. 3 is a schematic enlarged rear view of area A in FIG. 2.

FIG. 4 is a schematic enlarged cross-sectional view of area B of FIG. 2.

FIGS. 5 to 11 are schematic view illustrating a manufacturing method of a display device of FIG. 2 according to an embodiment.

FIG. 12 is a schematic cross-sectional view illustrating a manufacturing method of a display device of FIG. 2 according to another embodiment.

FIGS. 13 and 14 are schematic views illustrating a display device according to another embodiment.

FIGS. 15 to 21 are schematic views illustrating a manufacturing method of the display device of FIG. 13.

FIG. 22 is a schematic view illustrating a display device according to another embodiment.

### DETAILED DESCRIPTION OF THE EMBODIMENTS

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be more thorough and complete, and will convey the scope of the disclosure to those skilled in the art. Like reference numerals refer to like elements throughout.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.”

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

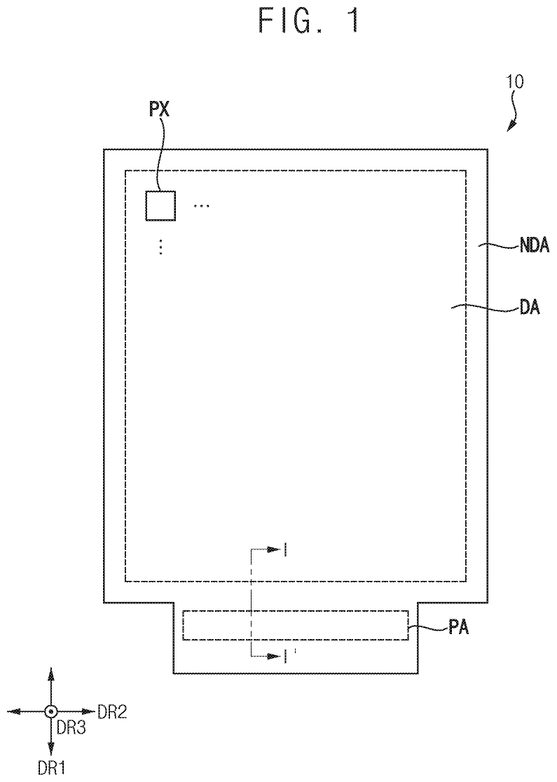

FIG. 1 is a schematic plan view illustrating a display device according to an embodiment.

Referring to FIG. 1, a display device 10 may include or may be divided into a display area DA and a non-display area NDA. The display area DA may display an image, and the non-display area NDA may be located adjacent to or around the display area DA. For example, the non-display area NDA may surround the display area DA.

In an embodiment, the display device 10 may have a rectangular shape in a plan view. However, the disclosure is not limited thereto, and the display device 10 may have various shapes in a plan view. A plane may be defined by a first direction DR1 and a second direction DR2 crossing (or intersecting) the first direction DR1. A third direction DR3 may be perpendicular to the plane. The third direction DR3 may be a front direction of the display device 10. In other words, the third direction DR3 may be a direction in which the image is displayed.

Pixels PX may be disposed in the display area DA. For example, the pixels PX may be entirely arranged in the display area DA in the first and second directions DR1 and DR2.

The non-display area NDA may include a pad area PA. The pad area PA may be located on at least one side of the display area DA. For example, as shown in FIG. 1, the pad area PA may be located in the first direction DR1 of the display area DA. However, the disclosure is not limited thereto.

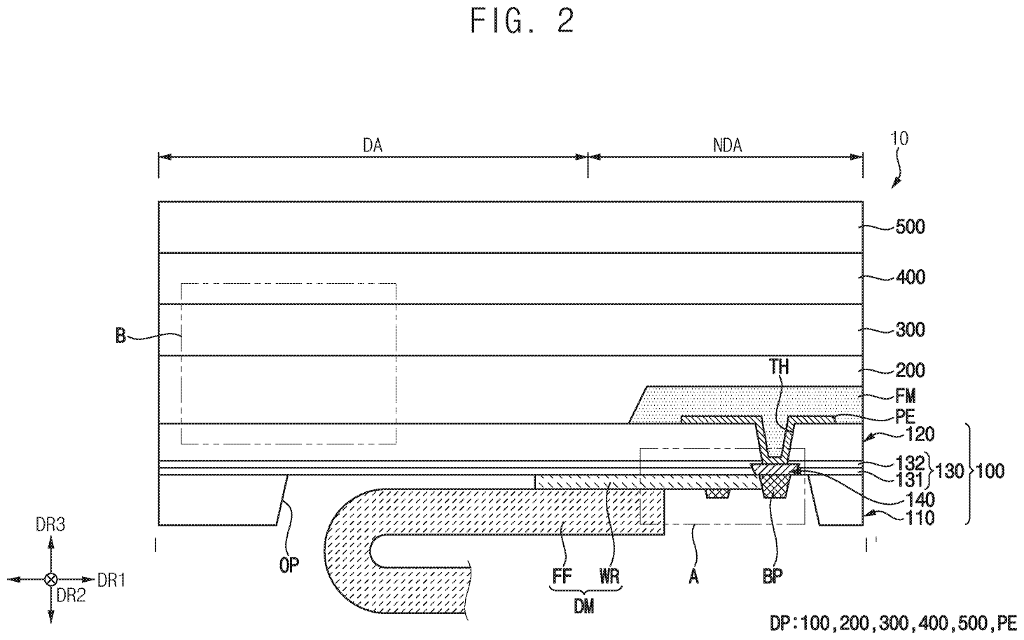

A pad electrode PE see FIG. 2) to be described below may be disposed in the pad area PA. The pad electrode PE may be electrically connected to an external device. For example, the pad electrode PE may electrically connect the external device and the pixels PX.

For example, the external device may be electrically connected to the display device 10 through a flexible printed circuit board. The external device may provide, e.g., at least one of a data signal, a gate signal, an emission control signal, a gate initialization signal, an initialization voltage, a power supply voltage, and the like to the display device 10.

A driver may be disposed in the non-display area NDA. The driver may provide signals and/or voltages to the pixels PX. For example, the driver may include a data driver and a gate driver.

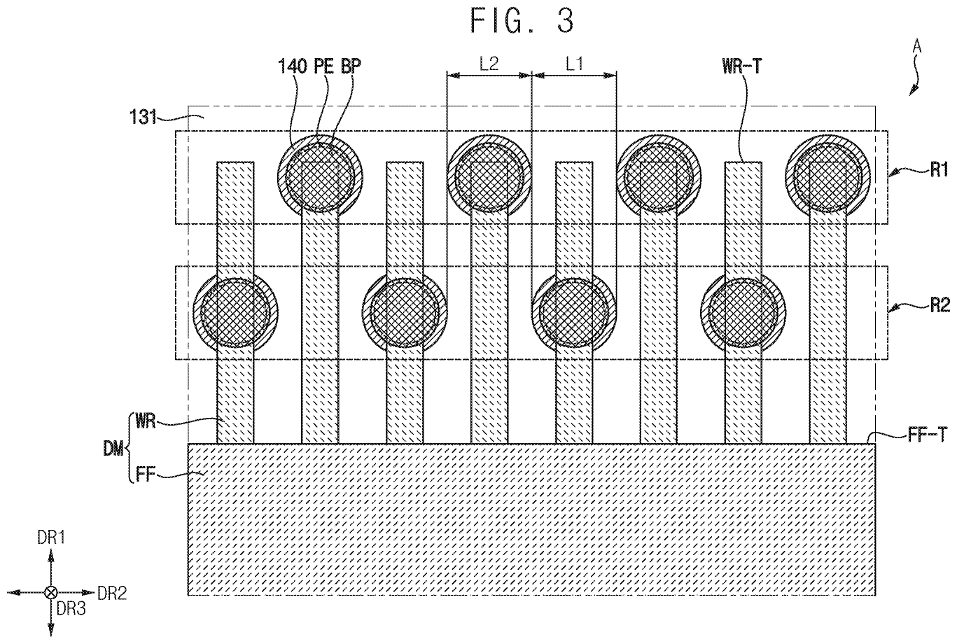

FIG. 2 is a schematic cross-sectional view taken along line I-I′ in FIG. 1, and FIG. 3 is a schematic enlarged rear view of area A in FIG. 2.

Referring to FIGS. 2 and 3, the display device 10 may include a display panel DP, a driving member DM, and/or bonding patterns BP. The display panel DP may include a substrate layer 100, a circuit device layer 200, a light emitting device layer 300, an encapsulation layer 400, and/or a protective film 500. The driving member DM may include connection wires WR and/or a flexible film FF. The bonding patterns BP may bond the display panel DP and the driving member DM. For example, the driving member DM may be bonded to the display panel DP in a direction opposite to the third direction DR3. For example, the driving member DM may be bonded to a rear surface of the display panel DP through the bonding patterns BP.

The substrate layer 100 may include a first substrate 110, a second substrate 120, a barrier layer 130, and/or connection electrodes 140.

The first substrate 110 may be a transparent insulating substrate. The first substrate 110 may have flexibility so as to be bendable, rollable, and/or foldable. Examples of materials that can be used as the first substrate 110 may include polyimide (PI), polyethersulfone (PES), polyacrylate (PAR), polyetherimide (PEI), polyethylene naphthalate (PEN), polyethylene terephthalate (PET), polyphenylene sulfide (PPS), polycarbonate (PC), cellulose acetate propionate (CAP), or the like. These may be used alone or in combination with each other. In an embodiment, the first substrate 110 may have an opening OP exposing a portion of a first barrier layer 131.

The connection electrodes 140 may be disposed on the first substrate 110. In detail, the connection electrodes 140 may overlap the opening OP of the first substrate 110. For example, the opening OP of the first substrate 110 may expose a portion of each of the connection electrodes 140. The connection electrodes 140 may electrically connect the pad electrode PE and the driving member DM. For example, the connection electrodes 140 may be disposed between the pad electrode PE and the connection wires WR and may contact the pad electrode PE and the connection wires WR.

The second substrate 120 may be disposed on the first substrate 110. The second substrate 120 may be disposed on the first substrate 110 and the connection electrodes 140. The second substrate 120 may be disposed between the connection electrodes 140 and the circuit device layer 200. In an embodiment, the second substrate 120 and the first substrate 110 may include substantially a same material.

The barrier layer 130 may be disposed between the first substrate 110 and the second substrate 120. For example, the connection electrodes 140 and the barrier layer 130 may be disposed on a same layer.

In an embodiment, the barrier layer 130 may include a first barrier layer 131 and/or a second barrier layer 132. For example, the first barrier layer 131 may be disposed on the first substrate 110, and the second barrier layer 132 may be disposed on the first barrier layer 131. For example, the first barrier layer 131 may be disposed between the first substrate 110 and the second barrier layer 132, and the second barrier layer 132 may be disposed between the first barrier layer 131 and the second substrate 120.

The first barrier layer 131 and the second barrier layer 132 may include an inorganic insulating material. Examples of the inorganic insulating material that can be used as the first barrier layer 131 and the second barrier layer 132 may include silicon oxide, silicon nitride, and silicon oxynitride. These may be used alone or in combination with each other.

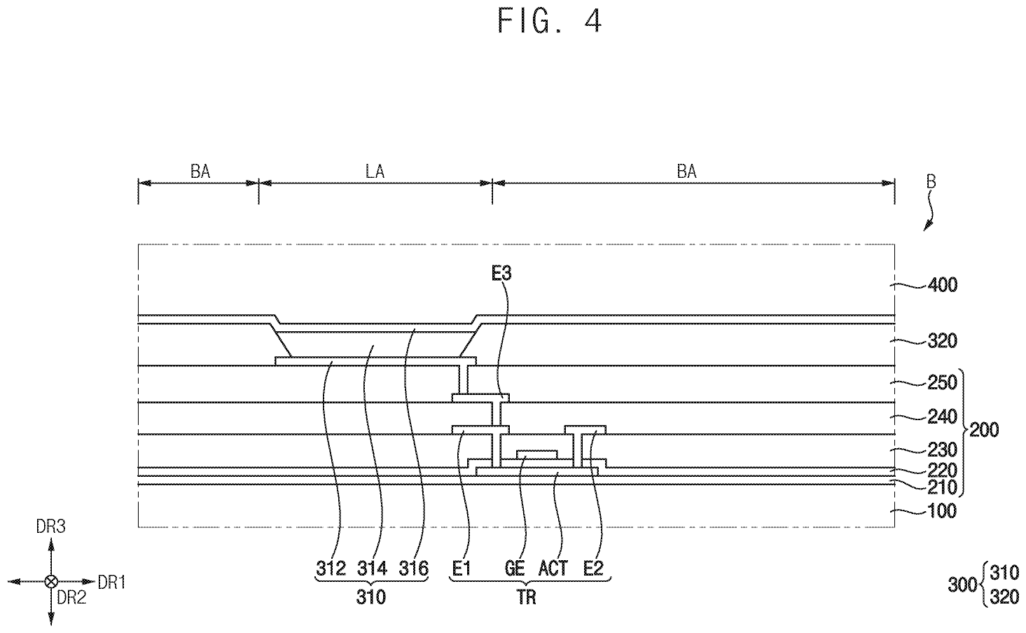

The circuit device layer 200 may be disposed on the substrate layer 100. The circuit device layer 200 may include at least one transistor. The light emitting device layer 300 may be disposed on the circuit device layer 200. The light emitting device layer 300 may include at least one light emitting device electrically connected to the transistor. The encapsulation layer 400 may be disposed on the light emitting device layer 300. The protective film 500 may be disposed on the encapsulation layer 400. A detailed description of the circuit device layer 200, the light emitting device layer 300, and the encapsulation layer 400 will be described below with reference to FIG. 4.

The pad electrode PE may be disposed on the first substrate 110. The pad electrode PE may be disposed on the connection electrodes 140. For example, the connection electrodes 140 may be disposed between the first substrate 110 and the pad electrode PE. The pad electrode PE may be electrically connected to the connection electrodes 140 and the transistor. The pad electrode PE may include, e.g., at least one of a metal, an alloy, a conductive metal oxide, a conductive metal nitride, a transparent conductive material, and the like.

In an embodiment, the second substrate 120 may have through holes TH overlapping the connection electrodes 140, respectively. For example, the through holes TH and the connection electrodes 140 may correspond to each other on a one-to-one basis. In an embodiment, the through holes TH may penetrate the second substrate 120 and the second barrier layer 132. The through holes TH may expose a portion of each of the connection electrodes 140. The pad electrode PE may be disposed on the second substrate 120 and may be electrically connected to the connection electrodes 140 through the through holes TH. For example, the pad electrode PE may directly contact the connection electrodes 140 through the through holes TH.

In an embodiment, the pad electrode PE may extend into each of the through holes TH. For example, as shown in FIG. 2, the pad electrode PE may cover (or overlap) side surfaces and a bottom surface of each of the through holes TH.

In an embodiment, filling member FM may be disposed inside the through holes TH. The filling member FM may compensate for a level difference (e.g., a height difference or step difference) by filling an inner space of the through holes TH. The filling member FM may contact the pad electrode PE. For example, the filling member FM may cover the pad electrode PE. In an embodiment, the filling member FM may include an organic material and/or inorganic material.

The connection electrodes 140 may be arranged to define rows extending in the second direction DR2 in a plan view. For example, as shown in FIG. 3, the connection electrodes 140 may be arranged to define a first row R1 extending in the second direction DR2 and a second row R2 extending in the second direction DR2. The second row R2 may be a row most adjacent to the first row R1. For example, the second row R2 may be adjacent to the first row R1 in a direction opposite to the first direction DR1. However, the disclosure is not limited thereto, and the connection electrodes 140 may be arranged to define three or more rows.

The connection electrodes 140 of the first row R1 may be arranged at a first interval L1 in the second direction DR2, and the connection electrodes 140 of the second row R2 may be arranged at a second interval L2 in the second direction DR2. In an embodiment, the first interval L1 and the second interval L2 may be same. For example, the interval between the connection electrodes 140 in the first row R1 and the interval between the connection electrodes 140 in the second row R2 may be substantially equal to each other. However, the disclosure is not limited thereto, and the first interval L1 may be greater than the second interval L2, or the first interval L1 may be smaller than the second interval L2.

In an embodiment, each of the first interval L1 and the second interval L2 may be in a range of about 10 um to about 100 um, specifically, about 10 um to about 50 um, and more specifically, about 10 um to about 20 um. In case that the above range is satisfied, bonding failure between the connection electrodes 140 and the connection wires WR can be further prevented or reduced.

The connection electrodes 140 may be arranged in a zigzag pattern in a plan view. For example, as shown in FIG. 3, the connection electrodes 140 of the first row R1 may be disposed between the connection electrodes 140 of the second row R2. For example, the connection electrodes 140 of the first row R1 may be disposed in a diagonal direction crossing the first direction DR1 and the second direction DR2 based on the connection electrodes 140 of the second row R2.

In an embodiment, the connection electrodes 140 of the second row R2 may not overlap the connection electrodes 140 of the first row R1 in the first direction DR1. However, the disclosure is not limited thereto, and the connection electrodes 140 of the second row R2 may at least partially overlap the connection electrodes 140 of the first row R1.

As the connection electrodes 140 may be arranged in a zigzag pattern in a plan view, the connection electrodes 140 may be arranged at a minute interval from each other, but poor bonding between the connection electrodes 140 and the connection wires WR may be prevented. Accordingly, reliability of the display device 10 may be improved, and display quality may be improved.

The connection electrodes 140 may correspond to the through holes TH exposing the pad electrode PE, and may have a planar shape to be arranged with the connection electrodes 140 which are neighboring at a minute interval. For example, as shown in FIG. 3, the connection electrodes 140 may have a circular planar shape. However, the disclosure is not limited thereto, and the connection electrodes 140 may have a planar shape such as a rectangle, a square, an ellipse, or a rhombus.

As shown in FIG. 2, the connection wires WR may be disposed in the opening OP of the first substrate 110. For example, the connection wires WR may be disposed under the first barrier layer 131. In an embodiment, the connection wires WR may extend in the first direction DR1. Also, as shown in FIG. 3, the connection wires WR may be spaced apart from each other in the second direction DR2. For example, respective portions of the connection wires WR may overlap the pad electrode PE in a plan view. Also, respective portions of the connection wires WR may overlap the connection electrodes 140 in a plan view. For example, the connection electrodes 140 may be disposed between the pad electrode PE and the connection wires WR. Accordingly, the connection wires WR may be electrically connected to the pad electrode PE through the connection electrodes 140.

The connection wires WR may include, e.g., a metal material. Examples of the metal material that can be used as the connection wires WR may include gold, copper, aluminum, tin, or the like. These may be used alone or in combination with each other.

The flexible film FF may be electrically connected to the connection wires WR. For example, the connection wires WR may be electrically connected to an end portion FF-T of the flexible film FF. In an embodiment, the end portions WR-T of each of the connection wires WR may protrude further in the first direction DR1 than the end portion FF-T of the flexible film FF. For example, the flexible film FF may expose portions of the connection wires WR to the outside. For example, portions of the connection wires WR overlapping the connection electrodes 140 may be exposed to the outside.

The flexible film FF may be formed of (or may include) a material having flexibility so as to be bendable. Examples of materials that can be used as the flexible film FF may include polyimide (PI), polyethersulfone (PES), polyacrylate (PAR), polyetherimide (PEI), polyethylene naphthalate (PEN), polyethylene terephthalate (PET), polyphenylene sulfide (PPS), polycarbonate (PC), cellulose acetate propionate (CAP), or the like. These may be used alone or in combination with each other. For example, the flexible film FF may be bent under the first substrate 110.

Although not shown, the flexible printed circuit board may be electrically connected to another end portion of the flexible film FF. Also, a driving integrated circuit may be mounted on the flexible film FF. However, this is only an example, and the disclosure is not limited thereto.

As shown in FIG. 2, the bonding patterns BP may be disposed in the opening OP of the first substrate 110. For example, as shown in FIG. 3, the bonding patterns BP may be arranged at positions where the connection electrodes 140 and the connection wires WR overlap each other in a plan view. For example, the bonding patterns BP may be arranged at positions corresponding to the connection electrodes 140. Accordingly, the bonding patterns BP may bond the connection wires WR and the connection electrodes 140 within the opening OP of the first substrate 110. Accordingly, the bonding patterns BP may bond the driving member DM to the rear surface of the display panel DP.

As the bonding patterns BP are arranged at the positions corresponding to the connection electrodes 140, the bonding patterns BP may be arranged to define rows extending in the second direction DR2 in a plan view. For example, as shown in FIG. 3, the bonding patterns BP may be arranged to define a first row R1 extending in the second direction DR2 and a second row R2 extending in the second direction DR2. However, the disclosure is not limited thereto, and the bonding patterns BP may be arranged to define three or more rows.

For example, the bonding patterns BP may be arranged in a zigzag pattern in a plan view. For example, as shown in FIG. 3, the bonding patterns BP of the first row R1 may be disposed between the bonding patterns BP of the second row R2. For example, the bonding patterns BP of the first row R1 may be disposed in a diagonal direction crossing the first direction DR1 and the second direction DR2 based on the bonding patterns BP of the second row R2.

In an embodiment, the bonding patterns BP of the second row R2 may not overlap the bonding patterns BP of the first row R1 in the first direction DR1. However, the disclosure is not limited thereto, and the bonding patterns BP of the second row R2 may at least partially overlap the bonding patterns BP of the first row R1.

The bonding patterns BP may correspond to the connection electrodes 140, and may have a planar shape to prevent bonding defects between the connection electrodes 140 and the connection wires WR. For example, as shown in FIG. 3, the bonding patterns BP may have a circular planar shape. However, the disclosure is not limited thereto, and the bonding patterns BP may have a planar shape such as a rectangle, a square, an ellipse, or a rhombus.

In an embodiment, the bonding patterns BP may include a conductive material. Examples of the conductive material that can be used as the bonding patterns BP may include silver (Ag), copper (Cu), chromium (Cr), aluminum (Al), or the like. These may be used alone or in combination with each other.

In an embodiment, a content of the conductive material included in each of the bonding patterns BP may be in a range of about 10 wt % to about 85 wt %, specifically about 10 wt % to about 60 wt %. In case that the above range is satisfied, bonding strength between the connection electrodes 140 and the connection wires WR may be further improved.

FIG. 4 is a schematic enlarged cross-sectional view of area B of FIG. 2.

Referring to FIGS. 2 and 4, the circuit device layer 200 may include a transistor TR, a buffer layer 210, a first insulating layer 220, a second insulating layer 230, a third insulating layer 240, and a fourth insulating layer 250. The transistor TR may include an active pattern ACT, a gate electrode GE, a first electrode E1, and a second electrode E2.

The buffer layer 210 may be disposed on the substrate layer 100. For example, the buffer layer 210 may be disposed on the second substrate 120. The buffer layer 210 may include an inorganic insulating material. The buffer layer 210 may prevent diffusion of impurities from the substrate layer 100 into the active pattern ACT.

The active pattern ACT may be disposed on the buffer layer 210. For example, the active pattern ACT may include a silicon semiconductor or an oxide semiconductor. The silicon semiconductor may include, e.g., at least one of amorphous silicon, polycrystalline silicon, and the like. The active pattern ACT may include a source area, a drain area, and a channel area. The channel area may be disposed between the source area and the drain area.

The first insulating layer 220 may be disposed on the buffer layer 210. The first insulating layer 220 may cover (or overlap) the active pattern ACT. The first insulating layer 220 may include an inorganic insulating material.

The gate electrode GE may be disposed on the first insulating layer 220. The gate electrode GE may overlap the channel area of the active pattern ACT. The gate electrode GE may include, e.g., at least one of a metal, an alloy, a conductive metal oxide, a conductive metal nitride, a transparent conductive material, and the like. For example, the gate electrode GE may be formed of silver (Ag), an alloy containing silver, molybdenum (Mo), an alloy containing molybdenum, aluminum (Al), an alloy containing aluminum, or aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The second insulating layer 230 may be disposed on the first insulating layer 220. The second insulating layer 230 may cover the gate electrode GE. The second insulating layer 230 may include an inorganic insulating material.

The first electrode E1 and the second electrode E2 may be disposed on the second insulating layer 230. The first electrode E1 and the second electrode E2 may be electrically connected to the source area and the drain area of the active pattern ACT through contact holes penetrating the first insulating layer 220 and the second insulating layer 230, respectively. The first electrode E1 and the second electrode E2 may include a metal, an alloy, a conductive metal oxide, a conductive metal nitride, a transparent conductive material, or the like. The active pattern ACT, the gate electrode GE, the first electrode E1 and the second electrode E2 may form the transistor TR.

The third insulating layer 240 may be disposed on the second insulating layer 230. The third insulating layer 240 may cover the first electrode E1 and the second electrode E2. The third insulating layer 240 may include an organic insulating material. Examples of the organic insulating material that can be used as the third insulating layer 240 may include photoresist, polyacryl-based resin, polyimide-based resin, polyamide-based resin, siloxane-based resin, acrylic-based resin, epoxy-based resin, or the like. These may be used alone or in combination with each other.

The third electrode E3 may be disposed on the third insulating layer 240. The third electrode E3 may be electrically connected to the first electrode E1 through a contact hole penetrating the third insulating layer 240. However, the disclosure is not limited thereto. For example, the third electrode E3 may contact the second electrode E2 through the contact hole penetrating the third insulating layer 240. The third electrode E3 may include, e.g., a metal, an alloy, a conductive metal oxide, a conductive metal nitride, a transparent conductive material, or the like. These may be used alone or in combination with each other.

In an embodiment, the third electrode E3 and the pad electrode PE may be disposed on a same layer. In other words, the third electrode E3 and the pad electrode PE may be formed by a same process. In other words, the third electrode E3 and the pad electrode PE may include a same material. However, the disclosure is not limited thereto, and the pad electrode PE and at least one of various conductive layers included in the circuit device layer 200 may be disposed on a same layer.

The fourth insulating layer 250 may be disposed on the third insulating layer 240. The fourth insulating layer 250 may cover the third electrode E3. The fourth insulating layer 250 may include an organic insulating material. Examples of the organic insulating material that can be used as the fourth insulating layer 250 may include photoresist, polyacryl-based resin, polyimide-based resin, polyamide-based resin, siloxane-based resin, acrylic-based resin, epoxy-based resin, or the like. These may be used alone or in combination with each other.

The light emitting device layer 300 may include a light emitting device 310 and a fifth insulating layer 320. The light emitting device 310 may include a lower electrode 312, a light emitting layer 314, and an upper electrode 316. Although FIG. 3 illustrates a light emitting area LA, first to third light emitting areas may be repeatedly disposed in the display device 10. The first to third light emitting areas may respectively emit light having different colors. For example, the first light emitting area may emit red light, the second light emitting area may emit green light, and the third light emitting area may emit blue light. Also, although FIG. 3 illustrates that a light blocking area BA has a relatively wide width, this is only an example, and the light blocking area BA may have a relatively narrow width.

The lower electrode 312 may be disposed on the fourth insulating layer 250. The lower electrode 312 may contact the third electrode E3 through a contact hole penetrating the fourth insulating layer 250. Accordingly, the lower electrode 312 may be electrically connected to the transistor TR. In another embodiment, the third electrode E3 may be omitted. The lower electrode 312 may directly contact the first electrode E1 or the second electrode E2. In an embodiment, the lower electrode 312 may be formed of metal, alloy, conductive metal oxide, transparent conductive material, or the like.

The fifth insulating layer 320 may be disposed on the fourth insulating layer 250. The fifth insulating layer 320 may partially cover the lower electrode 312 on the fourth insulating layer 250. The fifth insulating layer 320 may have a pixel opening exposing at least a portion of an upper surface of the lower electrode 312. The fifth insulating layer 320 may include an organic insulating material. Examples of the organic insulating material that can be used as the fifth insulating layer 320 may include photoresist, polyacryl-based resin, polyimide-based resin, polyamide-based resin. siloxane-based resin, acrylic-based resin, epoxy-based resin, or the like. These may be used alone or in combination with each other.

The light emitting layer 314 may be disposed on the lower electrode 312. For example, the light emitting layer 314 may be disposed on the lower electrode 312 exposed from the fifth insulating layer 320. In an embodiment, the light emitting layer 314 may have a multilayer structure including a hole injection layer, a hole transport layer, an organic emission layer, an electron transport layer, and an electron injection layer.

The upper electrode 316 may be disposed on the light emitting layer 314 and the fifth insulating layer 320. The light emitting layer 314 may emit light based on a voltage difference between the lower electrode 312 and the upper electrode 316.

The encapsulation layer 400 may be disposed on the light emitting device layer 300. For example, the encapsulation layer 400 may be disposed on the upper electrode 316. The encapsulation layer 400 may include at least one inorganic encapsulation layer and at least one organic encapsulation layer. The encapsulation layer 400 may prevent penetration of oxygen and moisture into the light emitting device layer 300 and/or the circuit device layer 200.

According to embodiments, the display device 10 may include the display panel DP and the driving member DM. The substrate layer 100 included in the display panel DP may include at least one of the first substrate 110, the second substrate 120, and the connection electrodes 140 disposed between the first substrate 110 and the second substrate 120. The pad electrode PE disposed on the substrate layer 100 may be electrically connected to the connection electrodes 140 through the through holes TH penetrating the second substrate 120. Also, the connection wires WR of the driving member DM may be electrically connected to the connection electrodes 140. Accordingly, the pad electrode PE and the connection wires WR may be electrically connected through the connection electrodes 140. Accordingly, the driving member DM may be bonded to the rear surface of the display panel DP. Thus, a dead space of the display device 10 may be reduced.

The connection electrodes 140 may be arranged in a zigzag pattern in a plan view. For example, the connection electrodes 140 may be arranged to define rows extending in a direction, and the connection electrodes 140 of the first row R1 among the rows may be disposed between the connection electrodes 140 of the second row R2 most adjacent to the first row R1 among the rows. Accordingly, the connection electrodes 140 may be arranged at a minute interval from each other, and bonding defects between the connection electrodes 140 and the connection wires WR may be prevented or reduced. Accordingly, reliability of the display device 10 may be improved, and display quality may be improved.

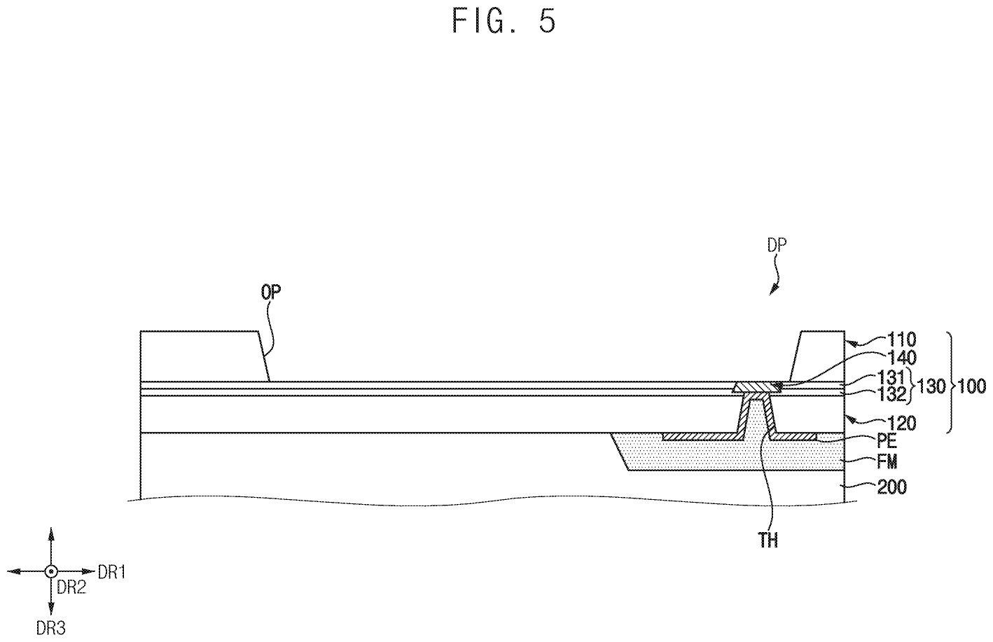

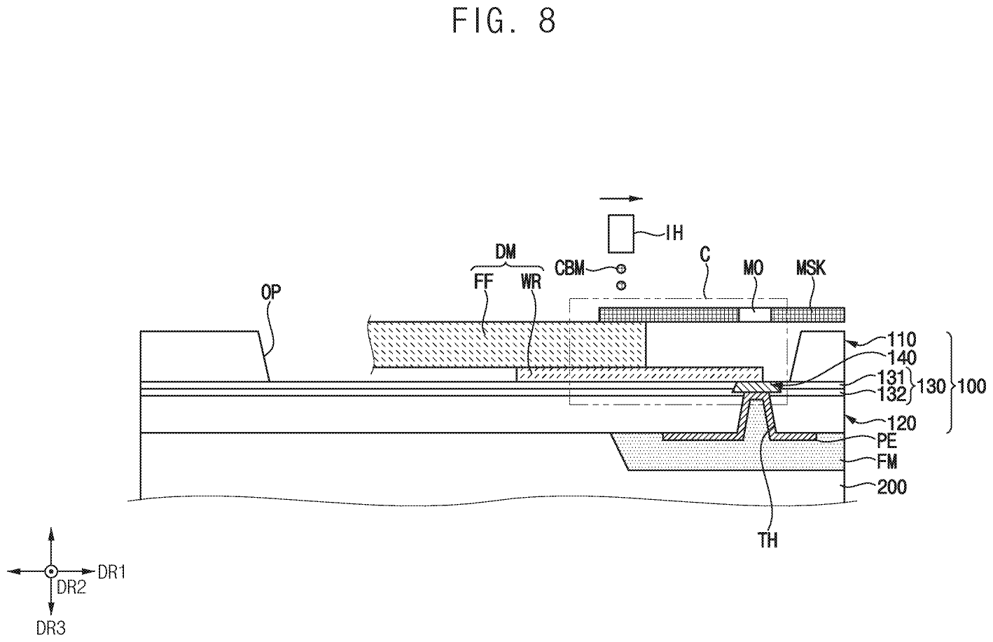

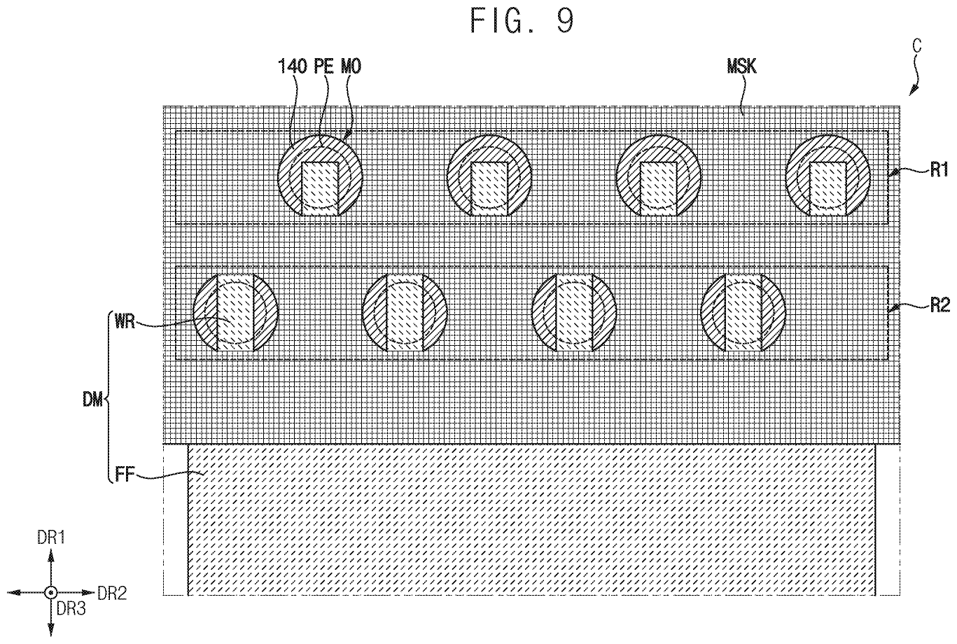

FIGS. 5 to 11 are schematic view illustrating a manufacturing method of a display device of FIG. 2 according to an embodiment. For example, FIG. 9 may be a schematic enlarged plan view of area C of FIG. 8.

Hereinafter, a method of manufacturing the display device 10 will be described with reference to FIGS. 5 to 11. For convenience of description, illustration of the layers above the circuit device layer 200 (e.g., the light emitting device layer 300, the encapsulation layer 400, and the protective film 500 of FIG. 2) among structures of the display panel DP will be omitted.

Referring to FIG. 5, the display panel DP including the substrate layer 100, the circuit device layer 200, and the pad electrode PE may be formed. The pad electrode PE may be formed on the substrate layer 100. The substrate layer 100 may include at least one of the first substrate 110, the second substrate 120 disposed on the first substrate 110, and the connection electrodes 140 disposed between the first substrate 110 and the second substrate 120. The pad electrode PE may be electrically connected to the connection electrodes 140 through the through holes TH penetrating the second substrate 120.

As described above with reference to FIG. 3, the connection electrodes 140 may be formed to define rows extending in the second direction DR2 in a plan view. For example, as shown in FIG. 3, the connection electrodes 140 may be formed to define the first row R1 extending in the second direction DR2 and the second row R2 extending in the second direction DR2.

Thereafter, the opening OP may be formed in the first substrate 110. For example, the connection electrodes 140 may be exposed by removing a portion of the first substrate 110. The opening OP may function as a space for attaching the driving member DM.

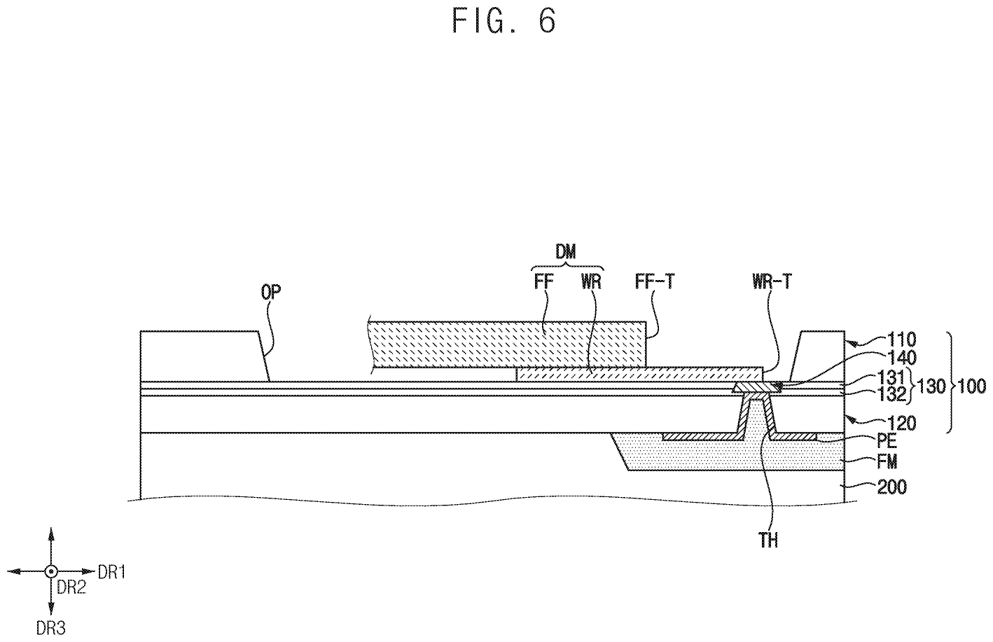

Further referring to FIG. 6, the driving member DM may be attached to the display panel DP. In an embodiment, the driving member DM may be attached to the display panel DP within the opening OP of the first substrate 110. For example, the driving member DM may be attached to the display panel DP so that respective portions of the connection wires WR overlap the connection electrodes 140, respectively. For example, the driving member DM may be attached to the rear surface of the display panel DP.

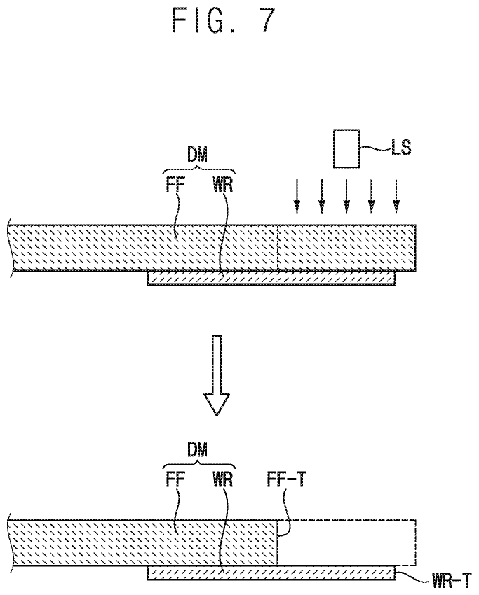

Referring further to FIG. 7, a process of processing the driving member DM may be preceded before attaching the driving member DM to the display panel DP. For example, a process of removing a portion of the flexible film FF so that the end portions WR-T of the connection wires WR protrude further in the first direction DR1 than the end portion FF-T of the flexible film FF, may be preceded. In an embodiment, a portion of the flexible film FF may be removed by a cutting process using a laser. As shown in FIG. 6, after the portion of the flexible film FF is removed, the driving member DM may be attached to the display panel DP, so that the connection electrodes 140 may overlap portions of the connection wires WR exposed from the flexible film FF in a plan view, respectively.

Referring to FIGS. 8 and 9, a mask MSK may be disposed on the display panel DP and the driving member DM. The mask MSK may be disposed on the connection wires WR exposed from the flexible film FF.

The mask MSK may have mask openings MO. The mask openings MO may be arranged to define rows extending in the second direction DR2 in a plan view. For example, as shown in FIG. 9, the mask openings MO may be arranged to define a first row R1 extending in the second direction DR2 and a second row R2 extending in the second direction DR2. However, the disclosure is not limited thereto, and the mask openings MO may be arranged to define three or more rows.

For example, the mask openings MO may be arranged in a zigzag pattern in a plan view. For example, as shown in FIG. 9, the mask openings MO of the first row R1 may be disposed between the mask openings MO of the second row R2. For example, the mask openings MO of the first row R1 may be disposed in a diagonal direction crossing the first direction DR1 and the second direction DR2 based on the mask openings MO of the second row R2.

In an embodiment, the mask openings MO of the second row R2 may not overlap the mask openings MO of the first row R1 in the first direction DR1. However, the disclosure is not limited thereto, and the mask openings MO of the second row R2 may at least partially overlap the mask openings MO of the first row R1.

The mask MSK may be disposed so that the mask openings MO overlap the connection electrodes 140 in a plan view, respectively. For example, the mask openings MO may be arranged at positions where the connection electrodes 140 and the connection wires WR overlap each other. Accordingly, the mask openings MO may expose the connection electrodes 140 and portions of the connection wires WR. For example, the mask openings MO may expose portions of the connection wires WR overlapping the connection electrodes 140. Accordingly, a conductive bonding material CBM may be selectively provided at the positions where the connection electrodes 140 and the connection wires WR overlap each other through the mask openings MO.

After the mask MSK is disposed, the conductive bonding material CBM may be provided to the positions where the connection electrodes 140 and the connection wires WR overlap each other through the mask openings MO.

The conductive bonding material CBM may include a conductive material. Examples of the conductive material that can be included in the conductive bonding material CBM may include silver (Ag), copper (Cu), chromium (Cr), aluminum (Al), or the like. These may be used alone or in combination with each other.

In an embodiment, a content of the conductive material included in the conductive bonding material CBM may be in a range of about 10 wt % to about 85 wt %, specifically about 10 wt % to about 60 wt %. In case that the above range is satisfied, bonding strength between the connection electrodes 140 and the connection wires WR may be further improved.

In an embodiment, as shown in FIG. 8, the conductive bonding material CBM may be provided by an inkjet printing process. For example, an inkjet head IH may be positioned on the mask MSK, and the conductive bonding material CBM may be ejected while the inkjet head IH is reciprocally moved in the first direction DR1. Accordingly, the conductive bonding material CBM may be selectively provided at the positions where the connection electrodes 140 and the connection wires WR overlap each other through the mask openings MO.

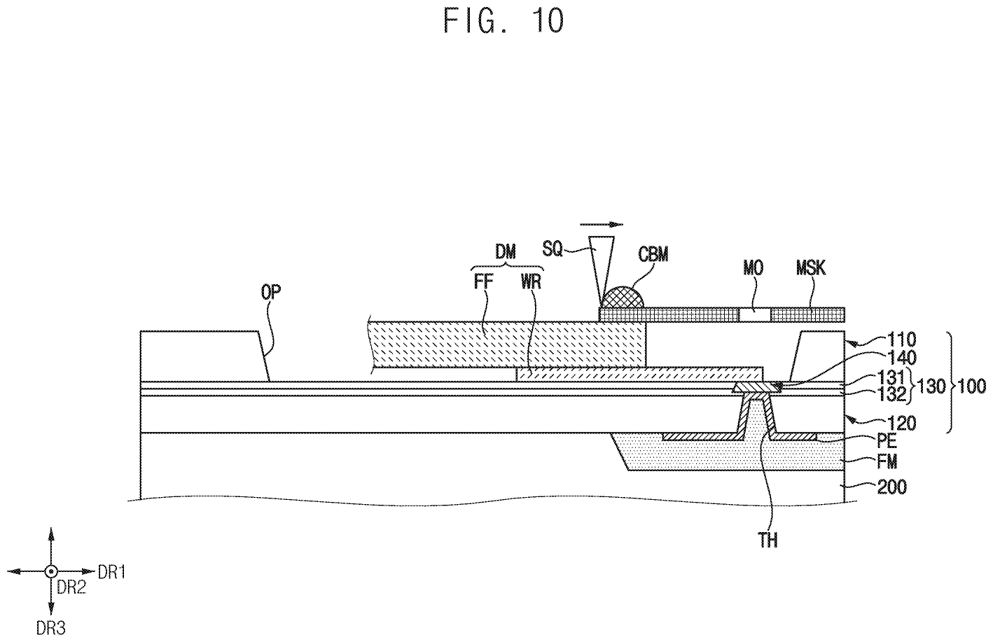

However, the disclosure is not limited thereto, and in another embodiment, as shown in FIG. 10, the conductive bonding material CBM may be provided by a screen printing process. For example, by placing the conductive bonding material CBM on the mask MSK and moving a squeeze rubber SQ in the first direction DR1, the conductive bonding material CBM may be pushed into the mask openings MO. Accordingly, the conductive bonding material CBM may be selectively provided at the positions where the connection electrodes 140 and the connection wires WR overlap each other through the mask openings MO.

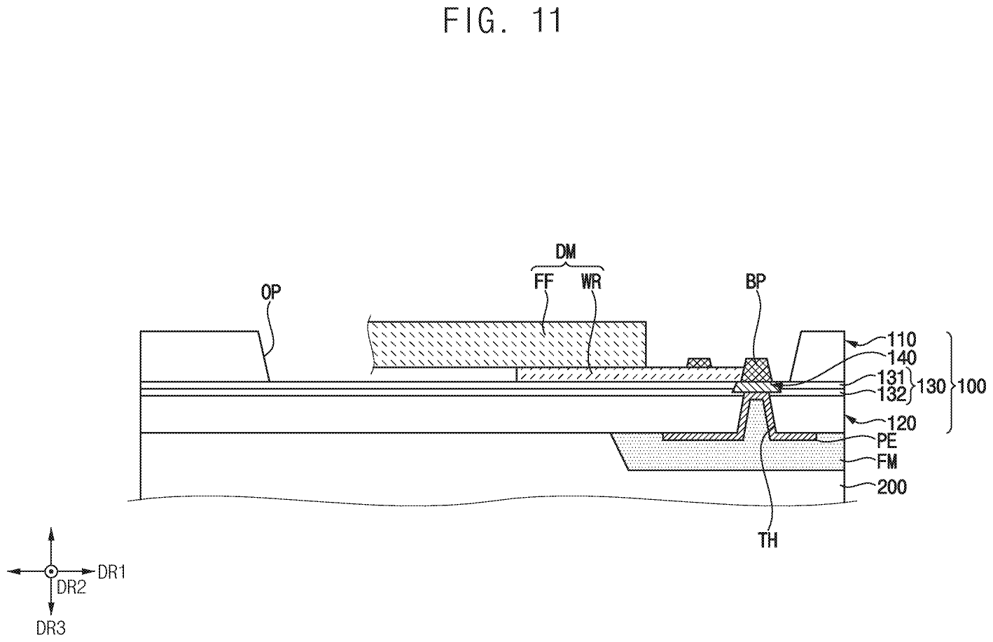

Referring further to FIG. 11, the bonding patterns BP may be formed by sintering the conductive bonding material CBM selectively provided at the positions where the connection electrodes 140 and the connection wires WR overlap each other. For example, the bonding patterns BP may be arranged at the positions where the connection electrodes 140 and the connection wires WR overlap each other. Accordingly, the connection wires WR and the connection electrodes 140 may be bonded by the bonding patterns BP. Accordingly, the driving member DM and the display panel DP may be bonded by the bonding patterns BP.

As the bonding patterns BP are formed at the positions corresponding to the connection electrodes 140 through the mask openings MO, as described above with reference to FIG. 3, the bonding patterns BP may be arranged to define rows extending in the second direction DR2. For example, as shown in FIG. 3, the bonding patterns BP may be formed to define the first row R1 extending in the second direction DR2 and the second rows R2 extending in the second direction DR2.

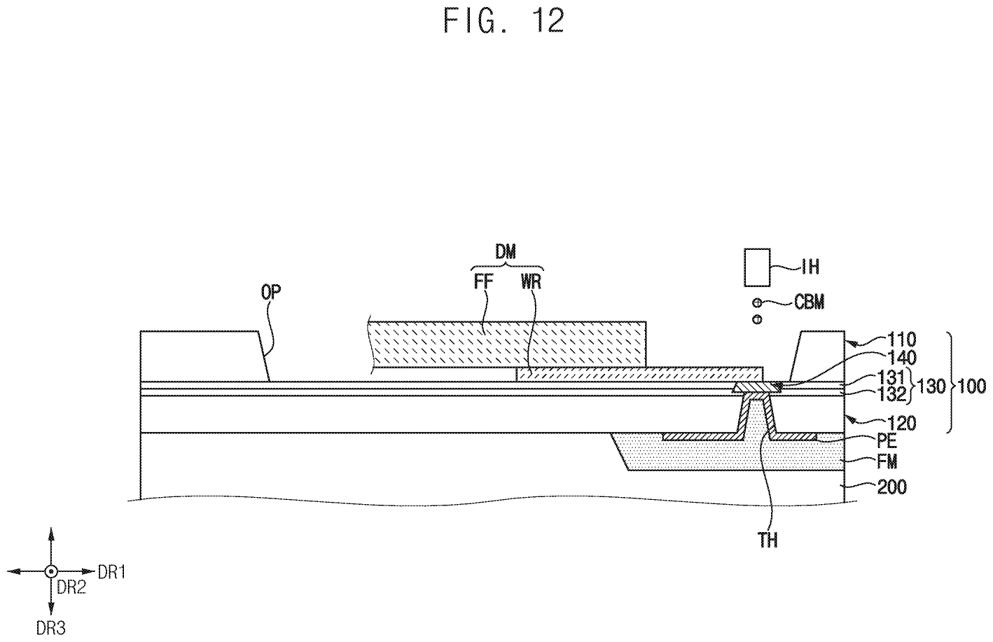

FIG. 12 is a schematic cross-sectional view illustrating a manufacturing method of a display device of FIG. 2 according to another embodiment. For example, FIG. 12 may correspond to the schematic cross-sectional view of FIG. 8.

Referring to FIG. 12, a method of manufacturing the display device 10 according to another embodiment may be substantially same as the method of manufacturing the display device 10 described with reference to FIGS. 5 to 10 except for omitting the mask MSK. Therefore, redundant descriptions may be omitted or simplified.

According to the manufacturing method of the display device 10 according to another embodiment, the conductive bonding material CBM may be directly ejected without the mask MSK at the positions where the connection electrodes 140 and the connection wires WR overlap each other. For example, as shown in FIG. 12, the conductive bonding material CBM may be directly ejected to the connection electrodes 140 and the connection wires WR by the inkjet head IH located at the positions where the connection electrodes 140 and the connection wires WR overlap each other.

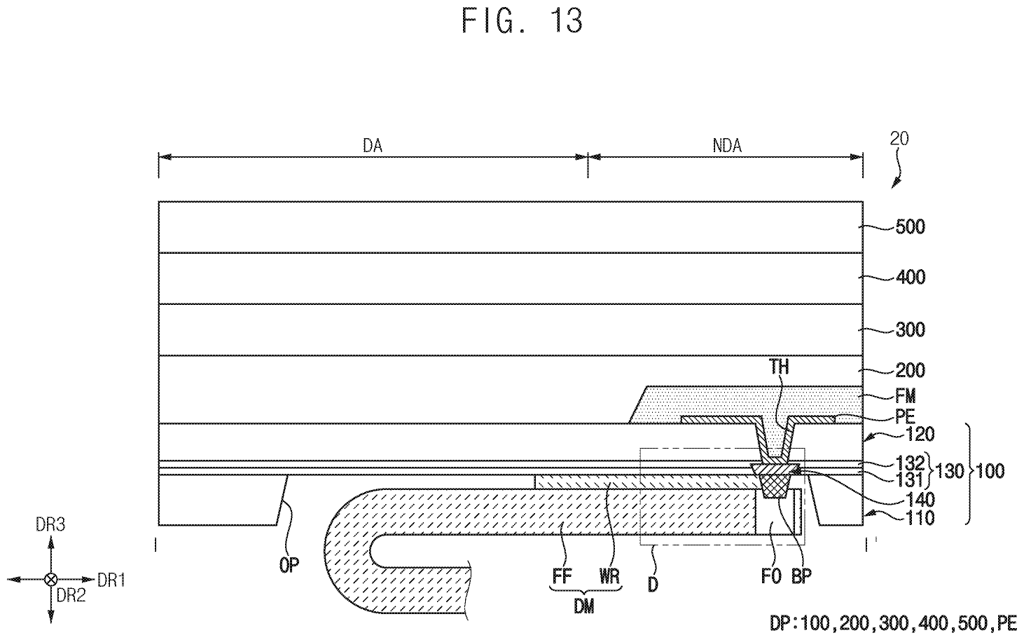

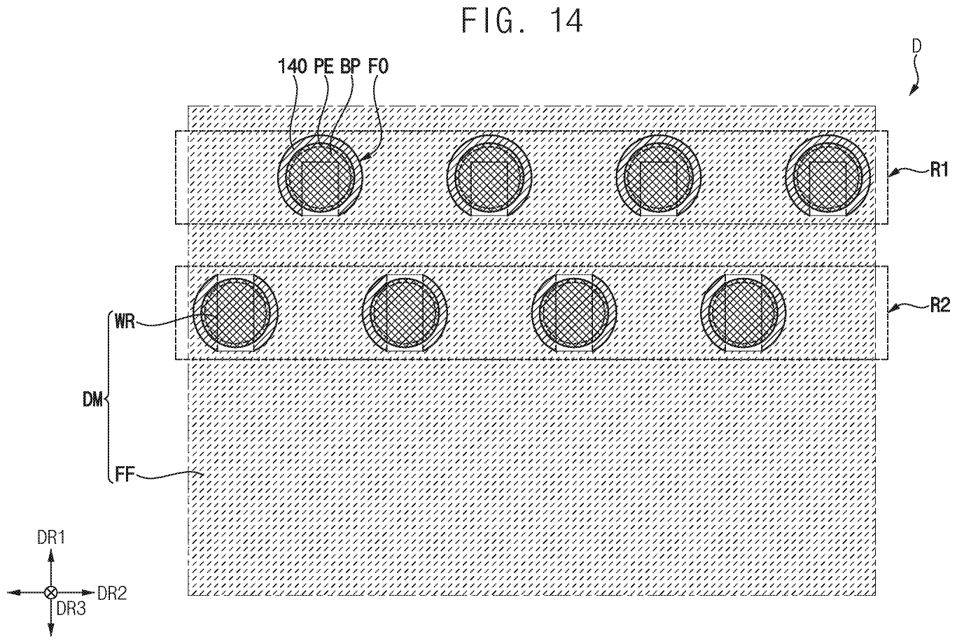

FIGS. 13 and 14 are schematic views illustrating a display device according to another embodiment. For example, FIG. 13 may be a schematic cross-sectional view of a display device 20 according to another embodiment, and FIG. 14 may be a schematic enlarged rear view of area D of FIG. 13. For example, FIG. 13 may correspond to the schematic cross-sectional view of FIG. 2 and FIG. 14 may correspond to the schematic rear view of FIG. 3.

Referring to FIGS. 13 and 14, the display device 20 according to another embodiment may be substantially same as the display device 10 described with reference to FIGS. 1 to 4 except for a structure of the driving member DM. Therefore, redundant descriptions may be omitted or simplified.

In an embodiment, the flexible film FF may cover the connection wires WR, but have film openings FO exposing respective portions of the connection wires WR.

The film openings FO may be arranged to define rows extending in the second direction DR2 in a plan view. For example, as shown in FIG. 14, the film openings FO may be arranged to define a first row R1 extending in the second direction DR2 and a second row R2 extending in the second direction DR2. However, the disclosure is not limited thereto, and the film openings FO may be arranged to define three or more rows.

For example, the film openings FO may be arranged in a zigzag pattern in a plan view. For example, as shown in FIG. 14, the film openings FO of the first row R1 may be disposed between the film openings FO of the second row R2. For example, the film openings FO of the first row R1 may be disposed in a diagonal direction crossing the first direction DR1 and the second direction DR2 based on the film openings FO of the second row R2.

In an embodiment, the film openings FO of the second row R2 may not overlap the film openings FO of the first row R1 in the first direction DR1. However, the disclosure is not limited thereto, and the film openings FO of the second row R2 may at least partially overlap the film openings FO of the first row R1.

The driving member DM may be disposed so that the film openings FO overlap the connection electrodes 140 in a plan view, respectively. For example, the film openings FO may be arranged at positions where the connection electrodes 140 and the connection wires WR overlap each other. Accordingly, the film openings FO may expose the connection electrodes 140 and portions of the connection wires WR. For example, the film openings FO may expose portions of the connection wires WR overlapping the connection electrodes 140. Accordingly, in the process of bonding the connection wires WR and the connection electrodes 140, the conductive bonding material may be selectively provided at the positions where the connection electrodes 140 and the connection wires WR overlap each other through the film openings FO. Accordingly, the film openings FO may overlap the bonding patterns BP formed from the conductive bonding material in a plan view, respectively.

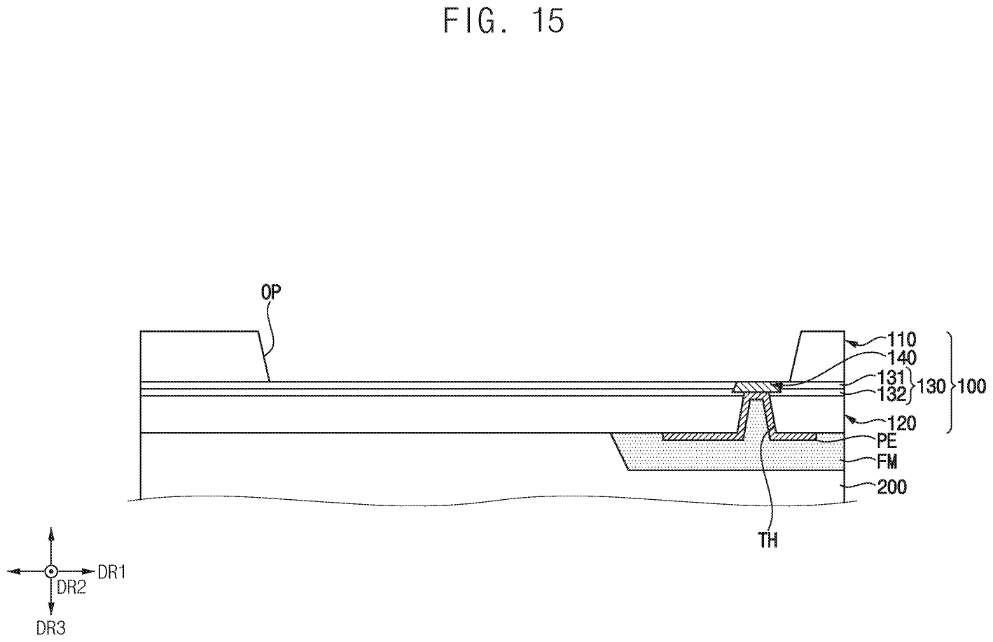

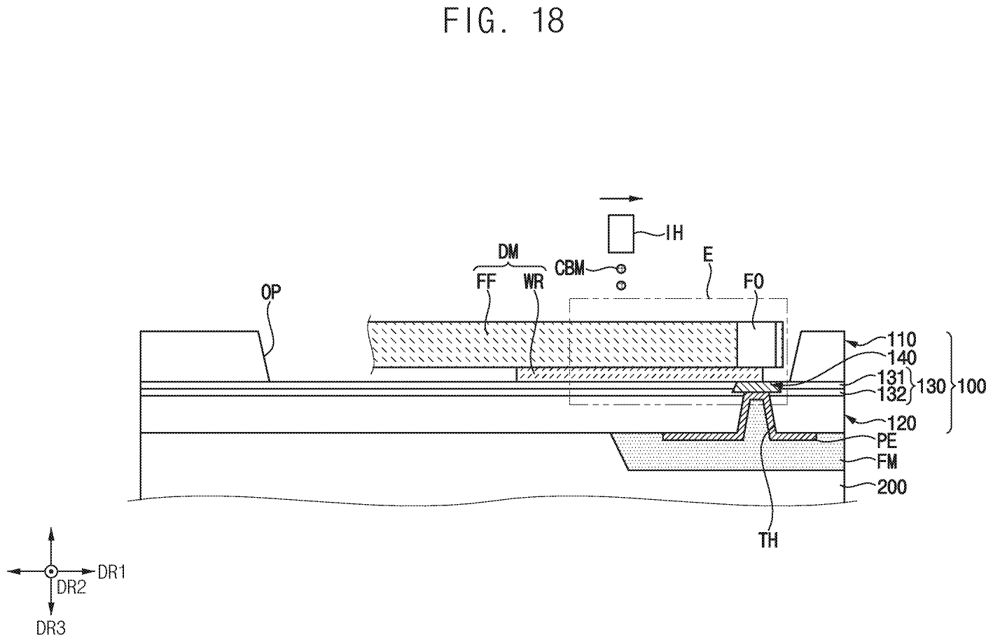

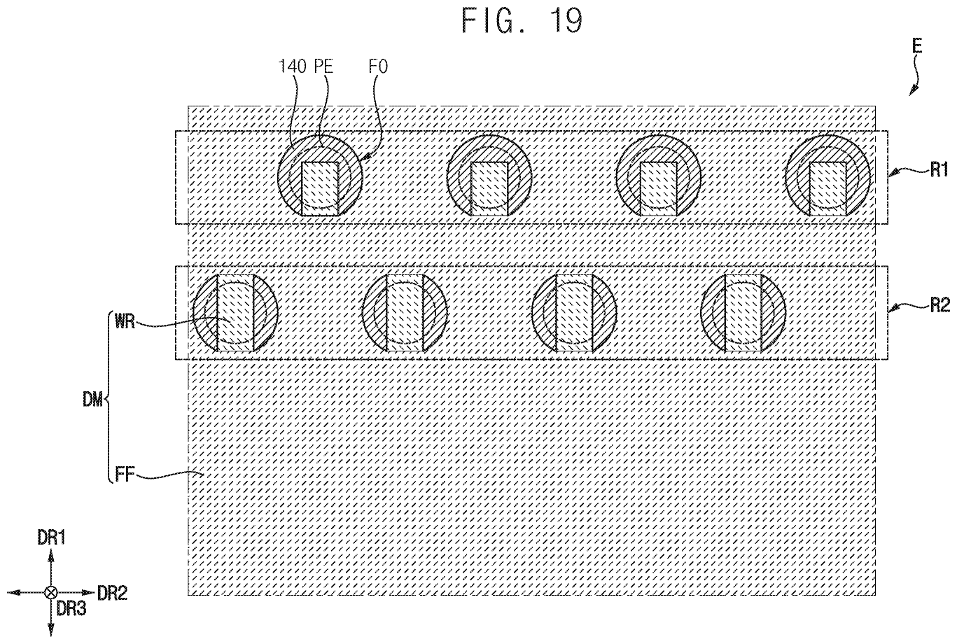

FIGS. 15 to 21 are schematic views illustrating a manufacturing method of the display device of FIG. 13. For example, FIG. 19 may be a schematic enlarged rear view of area E of FIG. 18.

Hereinafter, a manufacturing method of the display device 20 will be described with reference to FIGS. 15 to 20.

Referring to FIG. 15, the display panel DP including the substrate layer 100, the circuit device layer 200, and the pad electrode PE may be formed. The pad electrode PE may be formed on the substrate layer 100. The substrate layer 100 may include the first substrate 110, the second substrate 120 disposed on the first substrate 110, and the connection electrodes 140 disposed between the first substrate 110 and the second substrate 120. The pad electrode PE may be electrically connected to the connection electrodes 140 through the through holes TH penetrating the second substrate 120.

As described above with reference to FIG. 14, the connection electrodes 140 may be formed to define rows extending in the second direction DR2 in a plan view. For example, as shown in FIG. 14, the connection electrodes 140 may be formed to define the first row R1 extending in the second direction DR2 and the second row R2 extending in the second direction DR2.

Thereafter, the opening OP may be formed in the first substrate 110. For example, the connection electrodes 140 may be exposed by removing a portion of the first substrate 110. The opening OP may function as a space for attaching the driving member DM.

Referring to FIG. 6, the driving member DM may be attached to the display panel DP. In an embodiment, the driving member DM may be attached to the display panel DP within the opening OP of the first substrate 110. For example, the driving member DM may be attached to the display panel DP so that respective portions of the connection wires WR overlap the connection electrodes 140, respectively. For example, the driving member DM may be attached to the rear surface of the display panel DP.

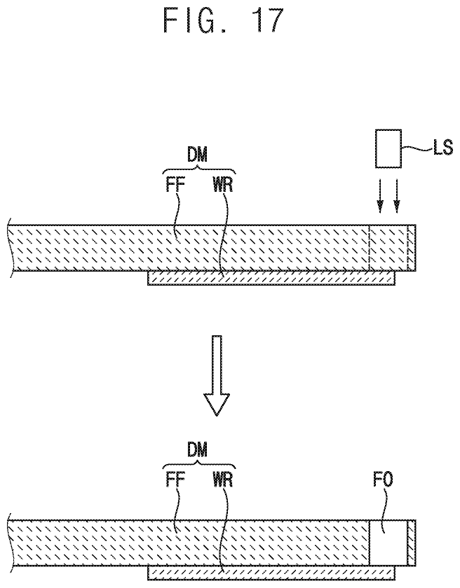

Referring further to FIG. 17, a process of processing the driving member DM may be preceded before attaching the driving member DM to the display panel DP. For example, a process of forming the film openings FO exposing portions of the connection wires WR in the flexible film FF may be preceded. In an embodiment, the film openings FO may be formed by removing portions of the flexible film FF using a laser LS. For example, the film openings FO may be formed by laser dot processing on the flexible film FF.

As described above with reference to FIG. 14, the film openings FO may be formed to define rows extending in the second direction DR2 in a plan view. For example, as shown in FIG. 14, the film openings FO may be formed to define the first row R1 extending in the second direction DR2 and the second row R2 extending in the second direction DR2.

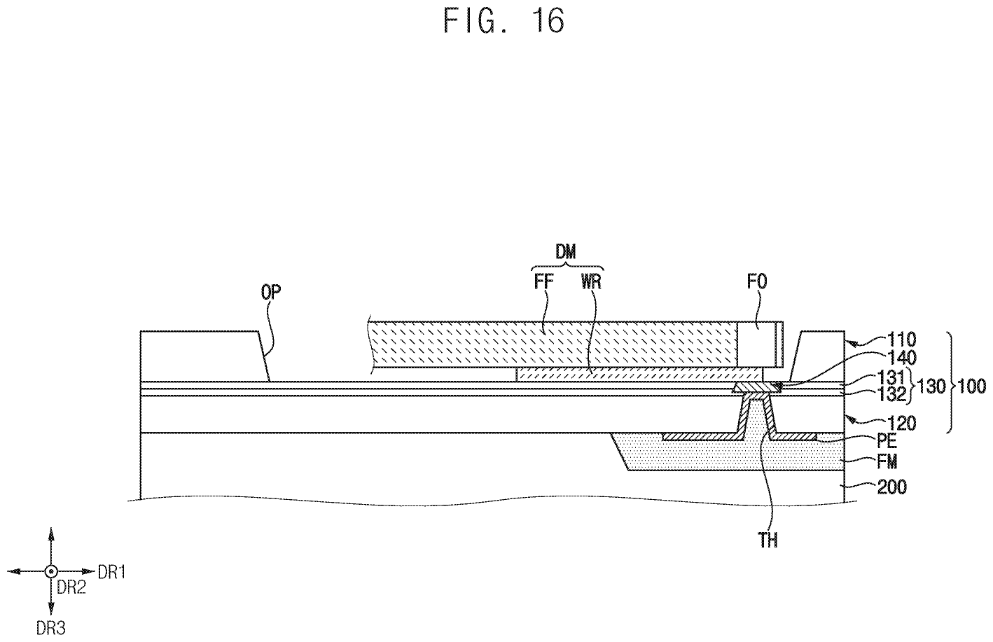

Accordingly, as shown in FIG. 16, as the driving member DM is attached to the display panel DP after the film openings FO are formed in the flexible film FF, the connection electrodes 140 may overlap the film openings FO in a plan view, respectively.

Referring to FIGS. 18 and 19, the conductive bonding material CBM may be provided at the positions where the connection electrodes 140 and the connection wires WR overlap each other through the film openings FO.

The conductive bonding material CBM may include a conductive material. Examples of the conductive material that can be included in the conductive bonding material CBM may include silver (Ag), copper (Cu), chromium (Cr), aluminum (Al), or the like. These may be used alone or in combination with each other.

In an embodiment, a content of the conductive material included in the conductive bonding material CBM may be in a range of about 10 wt % to about 85 wt %, specifically about 10 wt % to about 60 wt %. In case that the above range is satisfied, bonding strength between the connection electrodes 140 and the connection wires WR may be further improved.

In an embodiment, as shown in FIG. 18, the conductive bonding material CBM may be provided by an inkjet printing process. For example, the inkjet head IH may be positioned on the driving member DM (for example, the flexible film FF), and the conductive bonding material CBM may be ejected while the inkjet head IH is reciprocally moved in the first direction DR1. Accordingly, the conductive bonding material CBM may be selectively provided at the positions where the connection electrodes 140 and the connection wires WR overlap each other through the film openings FO.

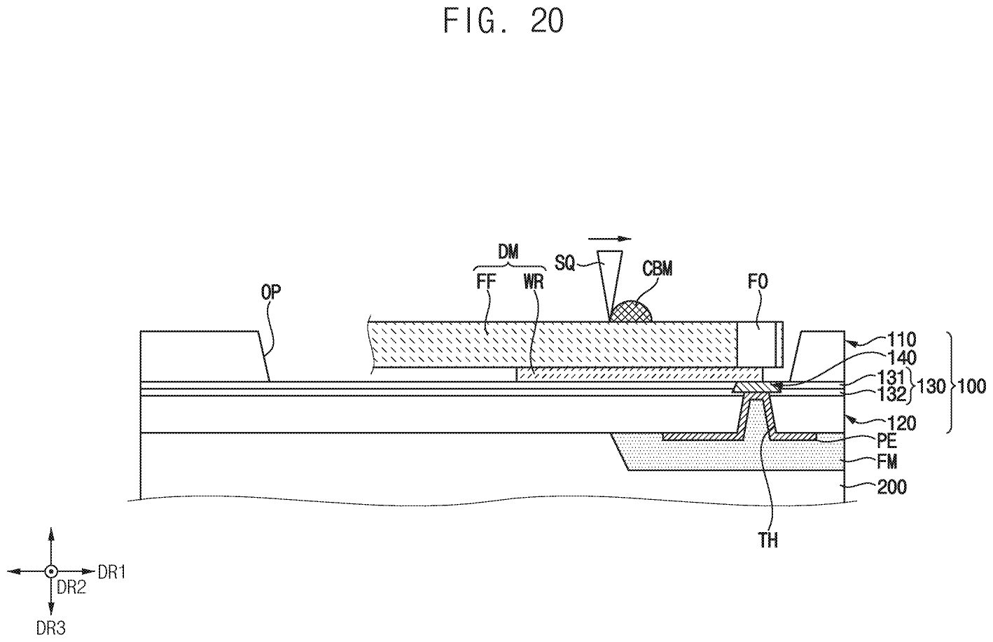

However, the disclosure is not limited thereto, and in another embodiment, as shown in FIG. 20, the conductive bonding material CBM may be provided by a screen printing process. For example, by placing the conductive bonding material CBM on the flexible film FF and moving a squeeze rubber SQ in the first direction DR1, the conductive bonding material CBM may be pushed into the film openings FO. Accordingly, the conductive bonding material CBM may be selectively provided at the positions where the connection electrodes 140 and the connection wires WR overlap each other through the film openings FO.

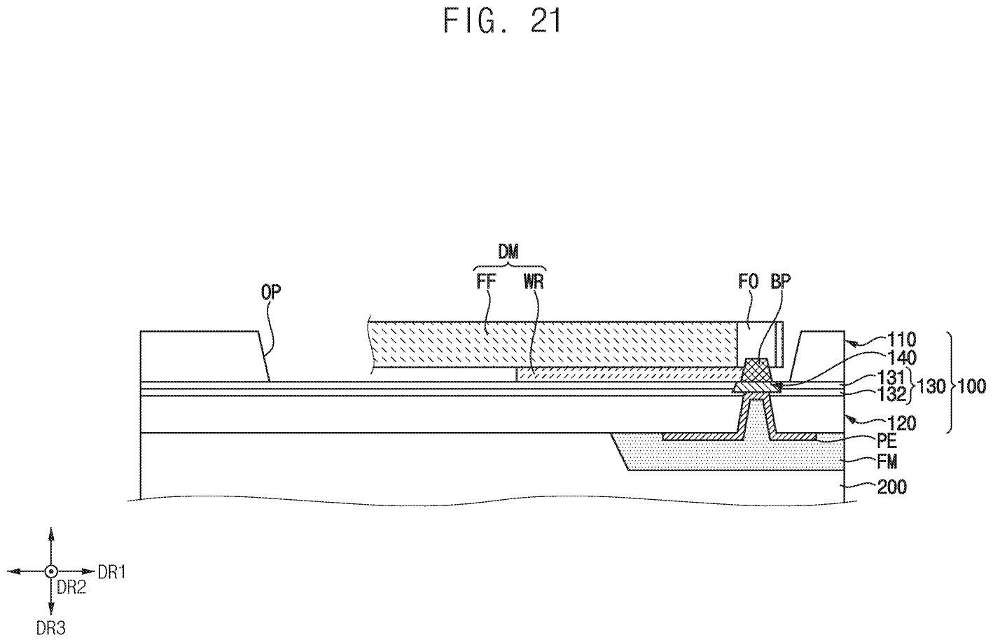

Referring further to FIG. 21, the bonding patterns BP may be formed by sintering the conductive bonding material CBM selectively provided at the positions where the connection electrodes 140 and the connection wires WR overlap each other. For example, the bonding patterns BP may be arranged at the positions where the connection electrodes 140 and the connection wires WR overlap each other. Accordingly, the connection wires WR and the connection electrodes 140 may be bonded by the bonding patterns BP. Accordingly, the driving member DM and the display panel DP may be bonded by the bonding patterns BP.

As the bonding patterns BP are formed at the positions corresponding to the connection electrodes 140 through the film openings FO, as described above with reference to FIG. 14, the bonding patterns BP may be arranged to define rows extending in the second direction DR2. For example, as shown in FIG. 14, the bonding patterns BP may be formed to define the first row R1 extending in the second direction DR2 and the second row R2 extending in the second direction DR2.

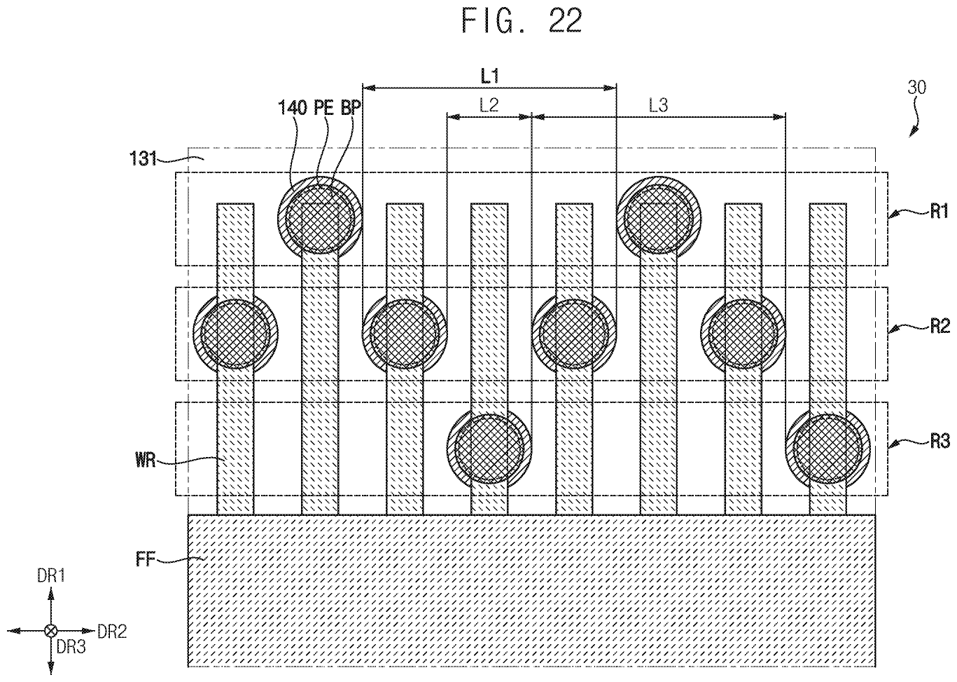

FIG. 22 is a schematic view illustrating a display device according to another embodiment. For example, FIG. 22 may correspond to the schematic rear view of FIG. 3.

Referring to FIG. 22, a display device 30 according to another embodiment may be substantially same as the display device 10 described with reference to FIGS. 1 to 4 except for an arrangement of the connection electrodes 140. Therefore, redundant descriptions may be omitted or simplified.

In an embodiment, the connection electrodes 140 may be arranged to define a first row R1 extending in the second direction DR2, a second row R2 extending in the second direction DR2, and a third row R3 extending in the second direction DR2. The second row R2 may be adjacent to the first row R1 in a direction opposite to the first direction DR1, and the third row R3 may be adjacent to the second row R2 in a direction opposite to the first direction DR1. For example, the second row R2 may be disposed between the first row R1 and the third row R3.

The connection electrodes 140 of the first row R1 may be arranged at a first interval L1 in the second direction DR2, the connection electrodes 140 of the second row R2 may be arranged at a second interval L2 in the second direction DR2, and the connection electrodes 140 of the third row R3 may be arranged at a third interval L3 in the second direction DR2. In an embodiment, the first interval L1 and the third interval L3 may be same. For example, the interval between the connection electrodes 140 in the first row R1 and the interval between the connection electrodes 140 in the third row R3 may be equal to each other. In an embodiment, the first interval L1 and the third interval L3 may be about three times of the second interval L2. However, the disclosure is not limited thereto, and the first interval L1, the second interval L2, and the third interval L3 may all be equal.

In an embodiment, the second interval L2 may be in a range of about 10 um to about 100 um, specifically, about 10 um to about 50 um, and more specifically, about 10 um to about 20 um. Each of the first interval L1 and the third interval L3 may be in a range of about 30 um to about 300 um, specifically, about 30 um to about 100 um, and more specifically, about 30 um to about 60 um. In case that the above range is satisfied, bonding failure between the connection electrodes 140 and the connection wires WR can be further prevented or reduced.

In an embodiment, the connection electrodes 140 of the first row R1 may be disposed between the connection electrodes 140 of the second row R2, and the connection electrodes 140 of the third row R3 may be disposed between the connection electrodes 140 of the second row R2.

In an embodiment, the connection electrodes 140 of the second row R2 may not overlap the connection electrodes 140 of the first row R1 and the connection electrodes 140 of the third row R3 in the first direction DR1. However, the disclosure is not limited thereto, and the connection electrodes 140 in each row R1, R2, or R3 may at least partially overlap each other in the first direction DR1.

Even in this case, the bonding patterns BP may be arranged at positions where the connection electrodes 140 and the connection wires WR overlap in plan view. As the bonding patterns BP are arranged at the positions corresponding to the connection electrodes 140, the bonding patterns BP may be arranged to define a first row R1 extending in the second direction DR2, a second row R2 extending in the second direction DR2, and a third row R3 extending in the second direction DR2. In addition, the bonding patterns BP of the first row R1 may be disposed between the bonding patterns BP of the second row R2, and the bonding patterns BP of the third row R3 may be disposed between the bonding patterns BP of the second row R2. The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first substrate having a flexibility;
a pad electrode disposed on the first substrate;
a driving member including:
connection wires extending in a first direction and electrically connected to the pad electrode; and
a flexible film connected to the connection wires; and
connection electrodes disposed between the pad electrode and the connection wires and arranged to define a plurality of rows extending in a second direction intersecting the first direction in a plan view.

2. The display device of claim 1, wherein the connection wires and the pad electrode are electrically connected through the connection electrodes.

3. The display device of claim 1, wherein the connection electrodes of a first row among the plurality of rows are disposed between the connection electrodes of a second row most adjacent to the first row among the plurality of rows in a plan view.

4. The display device of claim 1, further comprising:
bonding patterns overlapping the connection wires and the connection electrodes in a plan view and arranged to define a plurality of rows extending in the second direction in a plan view.

5. The display device of claim 4, wherein the connection wires and the connection electrodes are bonded by the bonding patterns.

6. The display device of claim 4, wherein
the first substrate has an opening exposing portions of each of the connection electrodes, and
wherein the connection wires and the connection electrodes are bonded by the bonding patterns in the opening.

7. The display of claim 4, wherein the bonding patterns of a first row among the plurality of rows are disposed between the bonding patterns of a second row most adjacent to the first row among the plurality of rows in a plan view.

8. The display device of claim 4, wherein the bonding patterns include a conductive material.

9. The display device of claim 8, wherein the conductive material included in each of the bonding patterns includes at least one selected from silver, copper, chromium, and aluminum.

10. The display device of claim 1, further comprising:
a second substrate disposed on the first substrate, and
wherein the connection electrodes are disposed between the first substrate and the second substrate.

11. The display device of claim 10, wherein
the second substrate has a through hole exposing portions of each of the connection electrodes, and
the pad electrode is electrically connected to the connection electrodes through the through hole.

12. The display device of claim 10, further comprising:
a barrier layer including:
a first barrier layer disposed on the first substrate; and a
second barrier layer disposed between the first barrier layer and the second substrate, and
wherein the connection electrodes and the barrier layer are disposed on a same layer.

13. The display device of claim 1, wherein end portions of the connection wires protrude further in the first direction than an end portion of the flexible film.

14. The display device of claim 1, wherein
the flexible film has film openings exposing portions of each of the connection wires and arranged to define a plurality of rows extending in the second direction in a plan view, and
the connection electrodes overlap the film openings in a plan view, respectively.

15. A method of manufacturing a display device, the method comprising:
forming a display panel including a first substrate having a flexibility, a pad electrode disposed on the first substrate, and connection electrodes electrically connected to the pad electrode;
attaching a driving member including connection wires extending in a first direction and a flexible film connected to the connection wires to the display panel such that portions of each of the connection wires overlaps the connection electrodes in a plan view, respectively; and
bonding the driving member and the display panel by providing a conductive bonding material on the connection wires overlapping the connection electrodes in a plan view, and
wherein the connection electrodes are arranged to define a plurality of rows extending in a second direction intersecting the first direction.

16. The method of claim 15, further comprising:
removing a portion of the flexible film so that end portions of the connection wires protrude further in the first direction than an end portion of the flexible film before the attaching of the driving member to the display panel, and
wherein after the attaching of the driving member to the display panel, the connection electrodes overlap portions of the connection wires exposed from the flexible film in a plan view, respectively.

17. The method of claim 16, wherein in the bonding of the driving member and the display panel, the conductive bonding material is ejected onto the connection wires overlapping the connection electrodes in a plan view by an inkjet printing process.

18. The method of claim 16, wherein
the bonding of the driving member and the display panel includes:
disposing a mask having mask openings arranged to define a plurality of rows extending in the second direction on the connection wires exposed from the flexible film; and
providing the conductive bonding material on the connection wires through the mask openings, and
after the disposing of the mask, the mask openings overlap the connection electrodes in a plan view, respectively.

19. The method of claim 15, further comprising:
forming film openings exposing portions of each of the connection wires in the flexible film before attaching the driving member to the display panel, and
wherein after attaching the driving member to the display panel, the connection electrodes overlap the film openings in a plan view, respectively.

20. The method of claim 19, wherein in the bonding of the driving member and the display panel, the conductive bonding material is provided on the connection wires through the film openings to bond the connection wires and the connection electrode.
